(19) United States
(12) Patent Application Publication
(10) Pub. No.: US 2024/0405177 A1
(43) Pub. Date: Dec. 5, 2024

(54) Display Apparatus

(71) Applicant: LG Display Co., Ltd., Seoul (KR)

(72) Inventors: Jun Young Jo, Paju-si (KR); Bung Goo Kim, Paju-si (KR); Hyoung Ho Ahn, Paju-si (KR); Hee Won Lee, Paju-si (KR); Hye Sun Jung, Paju-si (KR); Jae Kwang Lee, Paju-si (KR); Pyung Ho Choi, Paju-si (KR); Tae Yoon Kim, Paju-si (KR); Sang Hak Shin, Paju-si (KR); Hyoung Sun Park, Paju-si (KR)

(21) Appl. No.: 18/672,763

(22) Filed: May 23, 2024

(30) Foreign Application Priority Data
May 31, 2023 (KR) 10-2023-0070267

(51) Int. Cl. H01L 33/62; H01L 25/075; H01L 33/40

(52) U.S. Cl. CPC H01L 33/62; H01L 25/0753; H01L 33/40

(57) ABSTRACT

A display apparatus may include a plurality of pixels in a display area and a pixel comprises a plurality of sub-pixels, a plurality of first electrodes that extend in a first direction and are between the sub-pixels, a connection electrode between the plurality of first electrodes and configured to transmit a voltage, and a second electrode connected to the connection electrode and configured to apply the voltage to the plurality of sub-pixels.

### CROSS-REFERENCE TO RELATED APPLICATION

This application claims priority to and the benefit of Republic of Korea Patent Application No. 10-2023-0070267, filed May 31, 2023, which is hereby incorporated by reference in its entirety.

### BACKGROUND

### Field

The present specification relates to a display apparatus, and more particularly, to a display apparatus that can improve the efficiency thereof by reducing the occurrence of parasitic capacitance between a first electrode and a second electrode.

### Description of Related Art

As flat display apparatuses, liquid crystal display apparatuses and organic light-emitting display apparatuses are used.

The organic light-emitting display apparatus has the advantage of improved light-emitting efficiency, fast response speed, a wide viewing angle, and the like compared to the liquid crystal display apparatus. However, since the organic light-emitting display apparatus still has low light emission efficiency and includes organic materials, the organic light-emitting display apparatus is vulnerable to moisture and thus reliability and lifespan may be reduced.

Recently, a micro light-emitting diode display apparatus being an inorganic light-emitting display apparatus has been proposed.

The micro light-emitting diode display apparatus produces an image by disposing an inorganic light-emitting diode with a size of 100 μm or less in each pixel. In the micro light-emitting diode display apparatus, micro light-emitting diodes grown on a monocrystal substrate may be disposed on an array substrate of the display apparatus and connected to electrodes.

### SUMMARY

The array substrate is prepared by forming pixel driving circuits and wire layers on a substrate of the display apparatus.

A first electrode connected to a light-emitting element may be disposed on the array substrate of the display apparatus, the light-emitting element may be disposed on the array substrate, and then a second electrode may be disposed on the light-emitting element and the array substrate. The first electrode may apply a high-potential voltage to the light-emitting element, and the second electrode may apply a low-potential voltage to the light-emitting element, thereby driving the light-emitting element. When the first electrode and the second electrode overlap each other, parasitic capacitance may occur.

In this regard, the inventors of the present specification recognized the above-mentioned problems and invented a display apparatus having a structure capable of reducing parasitic capacitance between a first electrode and a second electrode vertically disposed.

An objective to be achieved according to an embodiment of the present specification is to provide a display apparatus that can improve a driving interference signal by securing a separation distance between a first electrode and a second electrode without additional processes.

The problems or limitations to be solved or addressed by the present specification are not limited to those mentioned above, and other problems or limitations not mentioned will be clearly understood by those skilled in the art from the following description.

In one embodiment, a display apparatus comprises: a plurality of pixels in a display area and a pixel from the plurality of pixels comprising a plurality of sub-pixels; a plurality of first electrodes that extend in a first direction, the plurality of first electrodes between the plurality of sub-pixels; a connection electrode between the plurality of first electrodes, the connection electrode configured to transmit a voltage; and a second electrode connected to the connection electrode, the second electrode configured to apply the voltage from the connection electrode to the plurality of sub-pixels.

In one embodiment, a display apparatus comprises: a substrate; a plurality of pixels on the substrate; a pixel driving circuit on the substrate, the pixel driving circuit configured to drive the plurality of pixels; a buffer layer covering the pixel driving circuit and the substrate; a planarization layer on the buffer layer; a first insulating layer on the planarization layer; a connection electrode on a first portion of the planarization layer; a contact wire on a second portion of the planarization layer that is spaced apart from the first portion; a first electrode electrically connected to the contact wire; a light-emitting element on the contact wire; a second insulating layer on the light-emitting element and the first electrode; and a second electrode that electrically connects the connection electrode and the light-emitting element.

In one embodiment, a display apparatus comprises: a substrate; a plurality of pixels on the substrate; a plurality of first electrode connecting wires extending in a first direction; a contact wire extending from a first electrode connecting wire from the plurality of first electrode connecting wires to a pixel area of a pixel from the plurality of pixels in a second direction that intersects the first direction; a light-emitting element on the contact wire in the pixel area, the light-emitting element including a first electrode that is electrically connected to the contact wire; a connection electrode between a pair of first electrode connecting wires from the plurality of first electrode connecting wires; and a second electrode connecting wire on the light-emitting element and the contact wire, the second electrode electrically connected to the light-emitting element, wherein the connection electrode is non-overlapping with the second electrode connecting wire.

In one embodiment, a display apparatus comprises: a substrate; a planarization layer on the substrate having a first portion having a first height and a second portion having a second height that is higher than the first height; a plurality of signal lines on the first portion of the planarization layer, the plurality of signal lines extending in a first direction; a connection electrode between the plurality of signal lines on the first portion of the planarization layer, the connection electrode configured to transmit a voltage; a first insulation layer over the second portion of the planarization layer and over the plurality of signal lines and the connection electrode on the first portion of the planarization layer; a light emitting element on the second portion of the planarization layer; a second insulation layer including a first portion that covers the plurality of signal lines and a portion of the first insulation layer that is over the signal lines on the first portion of the planarization layer and a second portion that covers the light emitting element, the second portion of the planarization layer, and a portion of the first insulation layer that is on the second portion of the planarization layer; and a cathode electrode that is connected to the connection electrode and light emitting element, the cathode electrode over the first portion of the second insulation layer and the second portion of the second insulation layer.

Specific details of other exemplary embodiments are included in the detailed description and the accompanying drawings.

According to embodiments of the present specification, parasitic capacitance between a first electrode and a second electrode can be reduced by disposing an insulating layer with a high thickness on the first electrode.

According to embodiments of the present specification, the reliability of a display apparatus can be improved by improving driving signal interference between a first electrode and a second electrode while maintaining an electrical connection structure between a connection electrode and the second electrode. Accordingly, the display apparatus can be driven even with low power.

The effects of the present specification are not limited to the above-mentioned effects, and other effects that are not mentioned will be apparently understood by those skilled in the art from the following description and the appended claims.

### BRIEF DESCRIPTION OF THE DRAWINGS

FIG. 1 is a plan view illustrating of a display apparatus according to an embodiment of the present specification;

FIG. 2 is an enlarged plan view of a pixel part in FIG. 1 according to an embodiment of the present specification;

FIG. 3 is a cross-sectional view taken along line A-A′ in FIG. 2 according to an embodiment of the present specification;

FIG. 4 is a cross-sectional view taken along line B-B′ in FIG. 2 according to an embodiment of the present specification;

FIG. 5 is a plan view illustrating of a pixel part of a display apparatus according to an embodiment of the present specification;

FIG. 6 is a cross-sectional view taken along line A-A′ in FIG. 5 according to an embodiment of the present specification;

FIG. 7 is a cross-sectional view taken along line B-B′ in FIG. 5 according to an embodiment of the present specification;

FIG. 8 is a plan view illustrating of a pixel part of a display apparatus according to an embodiment of the present specification; and

FIG. 9 is a cross-sectional view taken along line C-C′ in FIG. 8 according to an embodiment of the present specification.

### DETAILED DESCRIPTION

Advantages and features of the present specification and methods of achieving them will become apparent with reference to preferable embodiments, which are described in detail, in conjunction with the accompanying drawings. However, the present specification is not limited to the embodiments to be described below and may be implemented in different forms, the embodiments are only provided to completely disclose the present disclosure and completely convey the scope of the present disclosure to those skilled in the art, and the present specification is defined by the disclosed claims.

Since the shapes, sizes, proportions, angles, numbers, and the like disclosed in the drawings for describing the embodiments of the present disclosure are only exemplary, the present disclosure is not limited to the illustrated items. The same reference numerals indicate the same components throughout the specification. Further, in describing the present disclosure, when it is determined that a detailed description of related known technology may unnecessarily obscure the gist of the present disclosure, the detailed description thereof will be omitted. When ‘including,’ ‘having,’ ‘comprising,’ and the like mentioned in the present specification are used, other parts may be added unless ‘only’ is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

Although first, second, and the like are used to describe various components, these components are not limited by these terms. These terms are only used to distinguish one component from another. Accordingly, a first component, which is mentioned, below may also be a second component within the technical spirit of the present specification.

The same reference numerals may refer to substantially the same elements throughout the present disclosure.

The size and thickness of each component shown in the drawings are shown for convenience of explanation, and the present invention is not necessarily limited to the size and thickness of the components shown.

Each feature of various embodiments of the present invention can be partially or entirely bonded to or combined with each other and can be linked and operated in technically various ways as a person skilled in the art can fully understand. The embodiments can be carried out independently of or in association with each other.

Hereinafter, a display apparatus according to embodiments of the present specification will be described in detail with reference to the accompanying drawings.

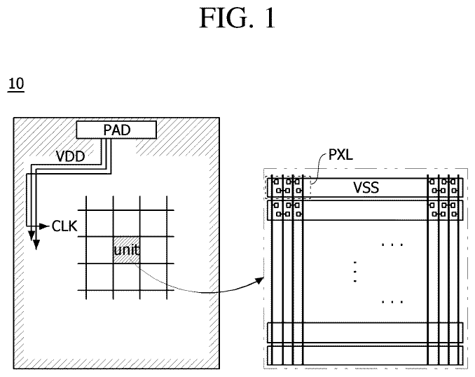

FIG. 1 is a plan view illustrating of a display apparatus 10 according to an embodiment of the present specification.

Referring to FIG. 1, the display apparatus 10 may include a display area where an image is displayed and a non-display area where no image is displayed and a driving circuit and wires for transmitting signals to the display area are disposed.

In the non-display area, the driving circuit may be mounted, and a pad unit PAD, to which an integrated circuit, a printed circuit, and the like are connected, may be disposed.

In the non-display area, a data driving circuit or a gate driving circuit may be disposed, and a controller signal for controlling a driving operation may be supplied.

The controller signal receives various input signals including a clock signal CLK, an input data enable signal, and a synchronization signal from the pad unit PAD.

The display apparatus 10 may drive a light-emitting element through a transistor connected to a driving voltage VDD. The driving voltage VDD is a high potential voltage EVDD and may be supplied to a pixel electrode or a first electrode of a driving transistor of each pixel PXL, and a common voltage VSS is a low potential voltage EVSS and may be supplied to a cathode electrode or a second electrode of the light-emitting element.

The display apparatus 10 may drive pixels by using a pixel driving circuit on a substrate. The pixel driving circuit may receive a driving voltage, an image signal (digital signal), a synchronization signal synchronized with the image signal, and the like, and output an anode voltage and a cathode voltage of the light-emitting element, thereby driving a plurality of pixels. The pixel driving circuit may receive an image signal and a synchronization signal from a host system. The host system may include a main board of a wearable system, a mobile system, a television (TV) system, a tablet computer, a laptop computer, a navigation system, or a personal computer (PC).

The common voltage VSS electrode may be commonly formed on the entire surface of the display apparatus, and may be commonly disposed for each pixel row as illustrated in FIG. 1.

One pixel PXL may include a pixel area, and one or more sub-pixels, for example, red, green, and blue sub-pixels may be disposed in the pixel area of the pixel PXL.

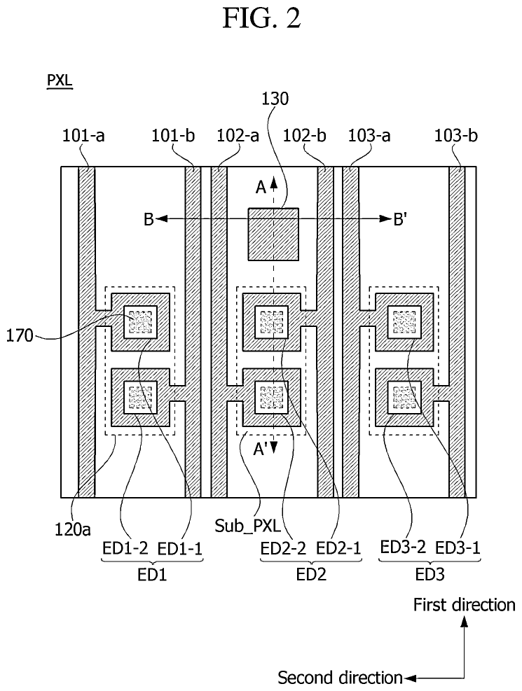

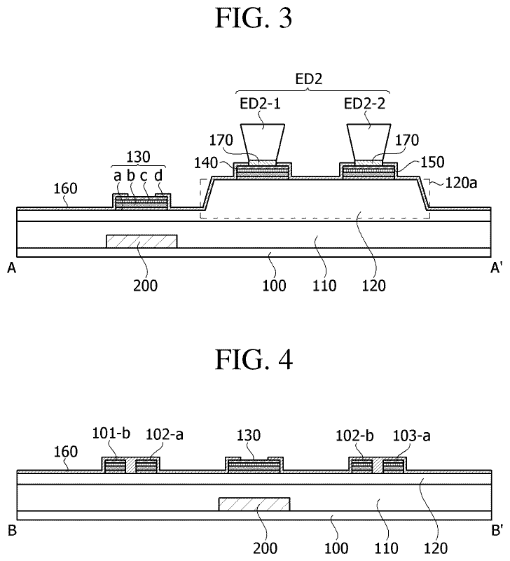

FIG. 2 is an enlarged plan view of the pixel part of FIG. 1 and FIGS. 3 and 4 are cross-sectional views of the pixel part of FIG. 1 according to an embodiment of the present specification.

One sub-pixel Sub_PXL may include at least one light-emitting element, and when one light-emitting element becomes defective, the luminance of the sub-pixel Sub_PXL may be adjusted by increasing the luminance of another light-emitting element.

The display apparatus 10 may include a pixel driving circuit 200, a buffer layer 110, a planarization layer 120, a connection electrode 130, a first contact wire 140, a second contact wire 150, and signal lines 101_a, 101_b, 102_a, 102_b, 103_a, and 103_b that are disposed on a substrate 100. In an embodiment, the signal lines may also be referred to as the first electrode connecting lines, the first electrode connecting wires, or first electrodes.

The substrate 100 may be made of plastic with flexibility. For example, the substrate 100 may be made in the form of a single layer or multiple layers of polyimide, polyethylene terephthalate, polyethylene naphthalate, polycarbonate, polyethersulfone, polyarylate, polysulfone, cyclic-olefin copolymer, or the like, but is not limited thereto. The substrate 100 may also be made of glass.

The pixel driving circuit 200 may be disposed on the substrate 100.

The pixel driving circuit 200 may include a plurality of thin-film transistors using an amorphous silicon semiconductor, a polycrystalline silicon semiconductor, or an oxide semiconductor. The plurality of thin-film transistors may include at least one driving thin-film transistor, at least one switching thin-film transistor, and at least one storage capacitor. When the pixel driving circuit 200 includes a plurality of thin-film transistors, the pixel driving circuit 200 may be formed on the substrate 100 through TFT manufacturing processes.

An adhesive layer may be made of acrylic resin, silicone resin, or the like, but is not limited thereto.

The buffer layer 110 covering the pixel driving circuit 200 may be disposed on the substrate 100. The buffer layer 110 may be made of an organic insulating material, for example, photosensitive photo acryl or photosensitive polyimide, but is not limited thereto.

The buffer layer 110 may be formed by stacking an inorganic insulating material, for example, silicon nitride (SiNₓ), silicon oxide (SiO₂), or the like, in multiple layers, and may be formed by stacking an organic insulating material and an inorganic insulating material in multiple layers.

The planarization layer 120 may be disposed on the buffer layer 110. The planarization layer 120 may be made of an organic insulating material, for example, photosensitive photo acryl or photosensitive polyimide, but is not limited thereto.

The planarization layer 120 in an area where light-emitting elements ED1, ED2, and ED3 are disposed may include a step area 120a thicker than the planarization layer 120 in an area where the light-emitting elements ED1, ED2, and ED3 are not disposed. That is, a second portion of the planarization layer 120 that overlaps the light-emitting elements ED1, ED2, and ED3 and the contact wires 140 may have a second thickness that is thicker than a first thickness of a first portion of the planarization layer 120 that is overlapping with the connection electrode 130 and signal lines 101, 102. In other words, the planarization layer includes the first portion having a first height and the second portion having a second height that is higher than the first height where the second portion corresponds to the step area 120a that overlaps the light-emitting elements.

When the step area 120a is formed in the planarization layer 120 where the light-emitting elements ED1, ED2, and ED3 are disposed and the light-emitting elements ED1, ED2, and ED3 are disposed on the planarization layer 120, the light-emitting elements ED1, ED2, and ED3 may be transferred to the step area 120a to facilitate alignment.

The pixel PXL may include the connection electrode 130 and the signal lines 101_a, 101_b, 102_a, 102_b, 103_a, and 103_b. The connection electrode 130 and the signal lines 101_a, 101_b, 102_a, 102_b, 103_a, and 103_b may transmit a high potential voltage EVDD and a low potential voltage EVSS, which are applied from the pad unit PAD or the pixel driving circuit 200, to each of the light-emitting elements ED1, ED2, and ED3.

The first contact wire 140 and the second contact wire 150 may extend from the signal lines 101_a, 101_b, 102_a, 102_b, 103_a, and 103_b, and may be connected to the light-emitting elements ED1, ED2, and ED3 to apply the high potential voltage EVDD to the signal lines 101_a, 101_b, 102_a, 102_b, 103_a, and 103_b.

The connection electrode 130, the signal lines 101_a, 101_b, 102_a, 102_b, 103_a, and 103_b, the first contact wire 140, and the second contact wire 150 may be formed on the planarization layer 120 by the same process.

The connection electrode 130, the signal lines 101_a, 101_b, 102_a, 102_b, 103_a, and 103_b, the first contact wire 140, and the second contact wire 150 may each be formed in a multi-layer structure including a first layer a, a second layer b, that is on the first layer a, a third layer c that is on the second layer b, and a fourth layer d that is on the third layer c. The first layer a, the second layer b, and the third layer c may each include titanium (Ti), molybdenum (Mo), or aluminum (Al).

The fourth layer d may include a transparent conductive oxide layer such as indium tin oxide (ITO) or indium zinc oxide (IZO) that is corrosion resistant and acid resistant.

The connection electrode 130, the signal lines 101_a, 101_b, 102_a, 102_b, 103_a, and 103_b, the first contact wire 140, and the second contact wire 150 may be disposed on the planarization layer 120.

A plurality of insulating layers including the buffer layer 110 and the planarization layer 120 on which the connection electrode 130 and the signal lines 101_a, 101_b, 102_a, 102_b, 103_a, and 103_b are formed, and the like may be formed with contact holes, and the connection electrode 130 may be electrically connected to the driving circuit 200 via metal wires disposed in the contact holes.

A first insulating layer 160 may be formed by stacking an inorganic insulating material, for example, silicon nitride (SiNₓ), silicon oxide (SiO₂), or the like in multiple layers.

The first insulating layer 160 may cover the connection electrode 130, signal lines 101_a, 101_b, 102_a, 102_b, 103_a, and 103_b, the first contact wire 140, and the second contact wire 150, and an opening may be formed on the connection electrode 130, the first contact wire 140, and the second contact wire 150. Thus, a portion of each of the connection electrode 130, the first contact wire 140, and the second contact wire 150 is non-overlapping with the first insulating layer 160.

An adhesive layer 170 may be disposed on the first contact wire 140 and the second contact wire 150. The adhesive layer 170 may be made of indium (In), tin (Sn), or an alloy thereof, but is not limited thereto.

The light-emitting elements ED1, ED2, and ED3 may be mounted on the first contact wire 140 and the second contact wire 150 by the adhesive layer 170. For example, one pixel PXL may include the light-emitting elements ED1, ED2, and ED3 of three colors. A first light-emitting element ED1 may be a red light-emitting element, a second light-emitting element ED2 may be a green light-emitting element, and a third light-emitting element ED3 may be a blue light-emitting element. Two light-emitting elements may be mounted on each sub-pixel Sub_PXL. One light-emitting element may be a main light-emitting element ED1-1, ED2-1, or ED3-1, and the other light-emitting element may be an auxiliary light-emitting element ED1-2, ED2-2, or ED3-2 (extra light-emitting element).

In an area where the adhesive layer 170 is not disposed on the first contact wire 140 and the second contact wire 150, top surfaces of the first layer a, the second layer b, and the third layer c may be exposed by removing a part of the first contact wire 140 and the second contact wire 150.

The first layer a, the second layer b, and the third layer c may each include titanium (Ti), molybdenum (Mo), or aluminum (Al) with high visible light reflectance, thereby further increasing light emission efficiency.

The first insulating layer 160 may cover the exposed top surfaces of the first layer a, the second layer b, and the third layer c to prevent the first layer a, the second layer b, and the third layer c from being corroded or damaged.

The light-emitting elements ED1, ED2, and ED3 may have different shapes and sizes depending on the light emission efficiency of each sub-pixel Sub_PXL.

As illustrated in the drawings, in the case of top emission, the light-emitting element may have an inverse tapered shape in order to increase light emission efficiency, and in the case of bottom emission, the light-emitting element may have a trapezoidal shape or a rectangular shape. That is, the inverse tapered shape of the light-emitting element includes an upper surface of the light-emitting element that is wider than a lower surface of the light-emitting element.

The light-emitting elements ED1, ED2, and ED3 may be inorganic light-emitting diodes. The inorganic light-emitting diodes may each have a size of 1 μm to 100 μm, 1 μm to 50 μm, or 1 μm to 20 μm in the horizontal direction (in the X-axis or Y-axis direction). The inorganic light-emitting diode may be referred to as a micro light-emitting diode. The inorganic light-emitting diode may include a p-doped semiconductor layer, an n-doped semiconductor layer, and an active layer therebetween (for example, including one or more quantum well layers). The inorganic light-emitting diode may include a first electrode connected to the p-doped semiconductor layer and a second electrode connected to the n-doped semiconductor layer. The inorganic light-emitting diodes may be manufactured using group II-VI or group III-V compound semiconductors. The inorganic light-emitting diode may be manufactured through a separate manufacturing process and may be disposed on the adhesive layer 170 through a transfer process.

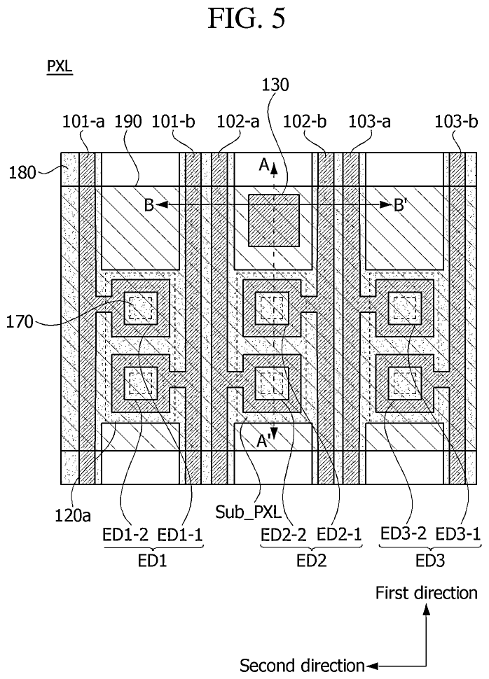

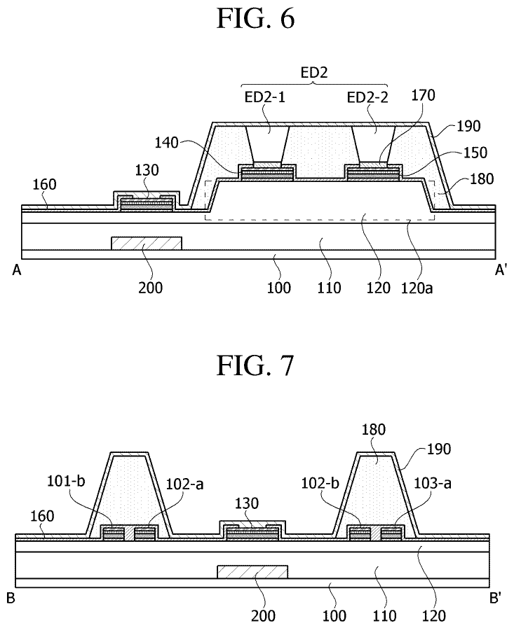

FIG. 5 is a plan view illustrating a pixel part of a display apparatus according to an embodiment of the present specification, and FIGS. 6 and 7 are cross-sectional views of a portion of FIG. 5 according to an embodiment of the present specification.

In describing the components of FIGS. 5 to 7, descriptions of components that are the same as or correspond to the components of FIGS. 2 to 4 are omitted or simplified.

A second insulating layer 180 may be disposed on the area where the light-emitting elements ED1, ED2, and ED3 are disposed and the signal lines 101_a, 101_b, 102_a, 102_b, 103_a, and 103_b. As shown in FIGS. 6 and 7, a first portion of the first insulation layer 160 is between the signal lines 101_b, 102_a (e.g., the first electrodes) and a first portion of the second insulating layer 180 and a second portion of the first insulating layer 160 is between the contact wire 140 and a second portion of the second insulating layer 180.

The second insulating layer 180 may be made of an organic insulating material and may further include scattering particles such as titanium dioxide. The second insulating layer 180 may surround the light-emitting elements ED1, ED2, and ED3, thereby improving the light emission effect.

The second insulating layer 180 is disposed on the step area 120a of the planarization layer 120 where the light-emitting elements ED1, ED2, and ED3 are disposed, and surrounds the side and top portions of the step area 120a of the planarization layer 120.

The second insulating layer 180 may be disposed on the signal lines 101_a, 101_b, 102_a, 102_b, 103_a, and 103_b along the first direction equal to the extension direction of the signal lines 101_a, 101_b, 102_a, 102_b, 103_a, and 103_b, and may be disposed with a wider width than the first insulating layer 160 on the signal lines 101_a, 101_b, 102_a, 102_b, 103_a, and 103_b.

The second insulating layer 180 may be formed to have a high thickness of 3 μm to 10 μm in order to surround the step area 120a and the light-emitting elements ED1, ED2, and ED3.

The second electrode 190 may be disposed on the second insulating layer 180 and the connection electrode 130 to extend in a second direction and cover all pixels PXL in the second direction. In an embodiment, the second electrode 190 may also be referred to as the second electrode connecting wire.

The second electrode 190 may be electrically connected to the connection electrode 130 and applies a voltage from the connection electrode to the sub-pixels. In one embodiment, the second electrode 190 may be made of a transparent conductive material. For example, the transparent conductive material may be indium-tin-oxide (ITO) or indium-zinc-oxide (IZO), but is not limited thereto.

The second electrode 190 may be in contact with and cover the top and side surfaces of the second insulating layer 180. That is, the second electrode 180 is on an upper surface and an inclined surface of a first portion of the second insulation layer 180 that covers the signal lines 101, 102 and is on an upper surface and an inclined surface of the second portion of the second insulation layer 180 that covers the light emitting element and step portion 120a of the planarization layer 120.

The second electrode 190 may commonly cover the pixels PXL in the second direction and may overlap the signal lines 101_a, 101_b, 102_a, 102_b, 103_a, and 103_b.

The second electrode 190 may be disposed on the second insulating layer 180 disposed on the signal lines 101_a, 101_b, 102_a, 102_b, 103_a, and 103_b to be maximally spaced apart from the signal lines 101_a, 101_b, 102_a, 102_b, 103_a, and 103_b, thereby reducing the occurrence of parasitic capacitance between the signal lines 101_a, 101_b, 102_a, 102_b, 103_a, and 103_b and the second electrode 190 by 80% or more compared to when the second insulating layer 180 is not disposed.

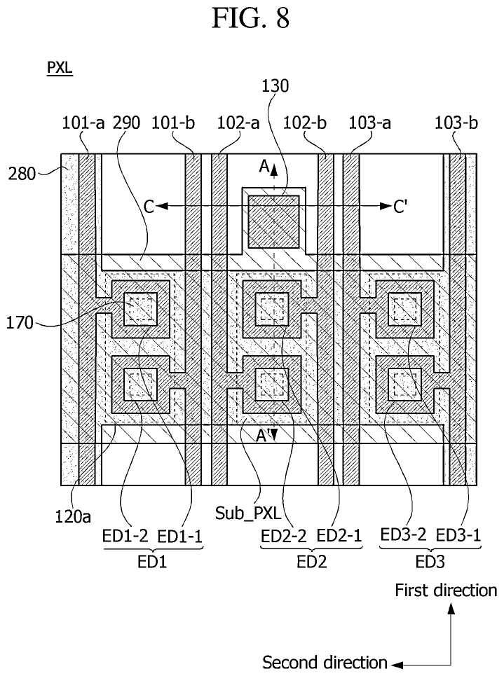

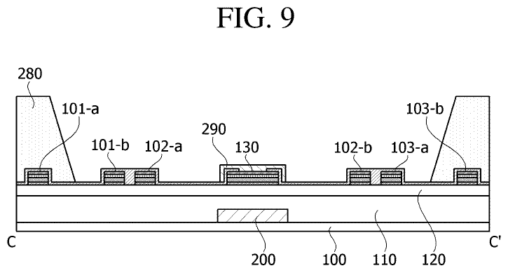

FIG. 8 is a plan view illustrating a pixel part of a display apparatus according to an embodiment of the present specification, and FIG. 9 is a cross-sectional view illustrating a portion of FIG. 8 along line C-C′ according to an embodiment of the present specification.

In describing the components of FIGS. 8 and 9, descriptions of components that are the same as or correspond to the components of FIGS. 5 to 7 are omitted or simplified.

For connection between the connection electrode 130 disposed on one side of the light-emitting element ED1, ED2, and ED3 and a second electrode 290 for each pixel PXL, the second electrode 290 may be disposed to extend to an area where the connection electrode 130 is disposed.

In this case, in order to reduce the occurrence of parasitic capacitance between the signal lines 101_a, 101_b, 102_a, 102_b, 103_a, and 103_b and the second electrode 290, the arrangement of the second electrode 290 in an area where the second insulating layer 280 is not disposed on the signal lines 101_a, 101_b, 102_a, 102_b, 103_a, and 103_b may be minimized or reduced.

In order to be connected to the connection electrode 130, the second electrode 290 extending in the second direction may partially extend in the first direction and may not be disposed on the signal lines 101_b, 102_a, 102_b, 103_a directly adjacent to both sides of the connection electrode 130.

The second insulating layer 280 may extend and may not be disposed on the signal lines 101_b, 102_a, 102_b, 103_a adjacent to both sides of the connection electrode 130, and is not disposed in an area of the signal lines 101_a, 101_b, 102_a, 102_b, 103_a, and 103_b where the second electrode 290 is not disposed, thereby minimizing an arrangement area of the second insulating layer 280 with a high thickness and reducing the material cost.

A black matrix and a light blocking layer may be disposed between each pixel PXL and the sub-pixel Sub_PXL in order to minimize or reduce light interference.

A passivation layer may be disposed on the second electrodes 190 and 290 in order to protect the second electrodes 190 and 290 and the light-emitting elements ED1, ED2, and ED3, and may be made of an inorganic insulating material or an organic insulating material.

On the passivation layer, a touch electrode for a touch operation of the display apparatus 10 may be formed or a touch panel may be disposed.

An optical film and a cover layer may be further included in the touch electrode and on the touch electrode, but the present disclosure is not limited thereto.

A display apparatus according to embodiments of the present specification may be described as follows.

A display apparatus according to embodiments of the present specification may include a plurality of pixels in a display area, the pixel comprising a plurality of sub-pixels, a plurality of first electrodes configured to extend in a first direction and disposed between the sub-pixels, a connection electrode disposed between the plurality of first electrodes, and a second electrode configured to apply a voltage to the plurality of sub-pixels, wherein the connection electrode may be connected to the second electrode.

According to one or more embodiments of the present specification, at least one connection electrode may be disposed for each pixel.

According to one or more embodiments of the present specification, the plurality of sub-pixels may comprise contact wires extending from the plurality of first electrodes in a second direction intersecting the first direction, and light-emitting elements disposed on the contact wires.

According to one or more embodiments of the present specification, the display apparatus may further comprise a first insulating layer disposed above the plurality of first electrodes.

According to one or more embodiments of the present specification, the display apparatus may further comprise a second insulating layer disposed on the plurality of first electrodes and the contact wire.

According to one or more embodiments of the present specification, the second insulating layer may overlap the plurality of first electrodes and be disposed to extend in the first direction.

According to one or more embodiments of the present specification, the second insulating layer and the second electrode may be not disposed above the plurality of first electrodes adjacent on both sides of the connection electrode.

According to one or more embodiments of the present specification, the second electrode may be disposed to extend on the plurality of pixels disposed in a second direction.

According to one or more embodiments of the present specification, the connection electrode and the contact wire may be made of the same material, and include at a plurality of metal layers.

According to one or more embodiments of the present specification, the display apparatus may further comprise an adhesive layer between the light-emitting element and the contact wire.

A display apparatus according to embodiments of the present specification may include a substrate, a plurality of pixels disposed on the substrate and a pixel driving circuit configured to drive the pixels, a buffer layer configured to cover the pixel driving circuit and the substrate, a planarization layer disposed on the buffer layer, a first insulating layer, a connection electrode, and a contact wire on the planarization layer, a first electrode connected to the contact wire; a light-emitting element disposed on the contact wire, a second insulating layer disposed on the light-emitting element and the first electrode and a second electrode configured to electrically connect the connection electrode and the light-emitting element.

According to one or more embodiments of the present specification, the first electrode and the second insulating layer may be disposed to extend in a first direction.

According to one or more embodiments of the present specification, the second insulating layer and the second electrode may be not disposed above the plurality of first electrodes adjacent on both sides of the connection electrode.

According to one or more embodiments of the present specification, the second electrode may be disposed to extend on the plurality of pixels disposed in a second direction.

According to one or more embodiments of the present specification, at least one connection electrode may be disposed for each pixel.

According to one or more embodiments of the present specification, the planarization layer may be thinner below the connection electrode than below the light-emitting element.

According to one or more embodiments of the present specification, the second insulating layer may be in contact with a top and a side of the planarization layer below the connection electrode.

According to one or more embodiments of the present specification, the connection electrode and the contact wire may be made of the same material, and include at least two metal layers.

According to one or more embodiments of the present specification, the display apparatus may further comprise an adhesive layer between the light-emitting element and the contact wire.

Although the embodiments of the present specification have been described in more detail with reference to the accompanying drawings, the present specification is not limited thereto and may be embodied in many different forms without departing from the technical concept of the present disclosure. Therefore, the embodiments disclosed in the present specification are provided for illustrative purposes only and are not intended to limit the technical concept of the present disclosure. The scope of the technical concept of the present specification is not limited thereto. Therefore, it should be understood that the above-described embodiments are illustrative in all aspects and do not limit the present specification.

What is claimed is:

1. A display apparatus comprising:
a plurality of pixels in a display area and a pixel from the plurality of pixels comprising a plurality of sub-pixels;
a plurality of first electrodes that extend in a first direction, the plurality of first electrodes between the plurality of sub-pixels;
a connection electrode between the plurality of first electrodes, the connection electrode configured to transmit a voltage; and
a second electrode connected to the connection electrode, the second electrode configured to apply the voltage from the connection electrode to the plurality of sub-pixels.

2. The display apparatus of claim 1, further comprising:
a plurality of connection electrodes including the connection electrode, each connection electrode connected to a corresponding pixel from the plurality of pixels.

3. The display apparatus of claim 1, wherein the plurality of sub-pixels comprise a plurality of contact wires extending from the plurality of first electrodes in a second direction intersecting the first direction, and a plurality of light-emitting elements included in the plurality of sub-pixels are on the plurality of contact wires.

4. The display apparatus of claim 3, further comprising:
a first insulating layer over the plurality of first electrodes.

5. The display apparatus of claim 4, further comprising:
a second insulating layer over the plurality of first electrodes and the plurality of contact wires such that a first portion of the first insulating layer is between the plurality of first electrodes and a first portion of the second insulating layer and a second portion of the first insulating layer is between the plurality of contact wires and a second portion of the second insulating layer.

6. The display apparatus of claim 5, wherein the second insulating layer overlaps the plurality of first electrodes and extends in the first direction.

7. The display apparatus of claim 6, wherein the second insulating layer and the second electrode are non-overlapping with first electrodes from the plurality of first electrodes that are directly adjacent on both sides of the connection electrode.

8. The display apparatus of claim 1, wherein the second electrode overlaps the plurality of pixels.

9. The display apparatus of claim 3, wherein the connection electrode and a contact wire from the plurality of contact wires comprise a same material, and include a plurality of metal layers.

10. The display apparatus of claim 3, further comprising:
an adhesive layer between a light-emitting element from the plurality of light-emitting elements and a contact wire from the plurality of contact wires.

11. A display apparatus comprising:
a substrate;
a plurality of pixels on the substrate;
a pixel driving circuit on the substrate, the pixel driving circuit configured to drive the plurality of pixels;
a buffer layer covering the pixel driving circuit and the substrate;
a planarization layer on the buffer layer;
a first insulating layer on the planarization layer;
a connection electrode on a first portion of the planarization layer;
a contact wire on a second portion of the planarization layer that is spaced apart from the first portion;
a first electrode electrically connected to the contact wire;
a light-emitting element on the contact wire;
a second insulating layer on the light-emitting element and the first electrode; and
a second electrode that electrically connects the connection electrode and the light-emitting element.

12. The display apparatus of claim 11, wherein the first electrode and the second insulating layer extend in a first direction.

13. The display apparatus of claim 11, wherein the second insulating layer and the second electrode are non-overlapping with first electrodes from a plurality of first electrodes that are directly adjacent to both sides of the connection electrode.

14. The display apparatus of claim 11, wherein the second electrode overlaps the plurality of pixels.

15. The display apparatus of claim 12, further comprising:
a plurality of connection electrodes including the connection electrode, each connection electrode connected to a corresponding pixel from the plurality of pixels.

16. The display apparatus of claim 11, wherein the second portion of the planarization layer that overlaps the light-emitting element and the contact wire is thicker than the first portion of the planarization layer that overlaps the connection electrode.

17. The display apparatus of claim 16, wherein the second insulating layer overlaps an upper surface and a side surface of the second portion of the planarization layer.

18. The display apparatus of claim 11, wherein the connection electrode and the contact wire comprise a same material, and include a plurality of metal layers.

19. The display apparatus of claim 11, further comprising:
an adhesive layer between the light-emitting element and the contact wire.

20. A display apparatus comprising:
a substrate;
a plurality of pixels on the substrate;
a plurality of first electrode connecting wires extending in a first direction;
a contact wire extending from a first electrode connecting wire from the plurality of first electrode connecting wires to a pixel area of a pixel from the plurality of pixels in a second direction that intersects the first direction;
a light-emitting element on the contact wire in the pixel area, the light-emitting element including a first electrode that is electrically connected to the contact wire;
a connection electrode between a pair of first electrode connecting wires from the plurality of first electrode connecting wires; and
a second electrode connecting wire on the light-emitting element and the contact wire,
the second electrode connecting wire electrically connected to the light-emitting element,
wherein the connection electrode is non-overlapping with the second electrode connecting wire.

21. The display apparatus of claim 20, further comprising:
an insulating layer on the plurality of first electrode connecting wires and the contact wire.

22. The display apparatus of claim 20, further comprising:
a planarization layer on the substrate, the planarization layer comprising a second portion that overlaps the light-emitting element and the contact wire that is thicker than a first portion of the planarization layer that overlaps the connection electrode.

23. A display apparatus comprising:
a substrate;
a planarization layer on the substrate having a first portion having a first height and a second portion having a second height that is higher than the first height;
a plurality of signal lines on the first portion of the planarization layer, the plurality of signal lines extending in a first direction;
a connection electrode between the plurality of signal lines on the first portion of the planarization layer, the connection electrode configured to transmit a voltage;
a first insulation layer over the second portion of the planarization layer and over the plurality of signal lines and the connection electrode on the first portion of the planarization layer;
a light emitting element on the second portion of the planarization layer;
a second insulation layer including a first portion that covers the plurality of signal lines and a portion of the first insulation layer that is over the plurality of signal lines on the first portion of the planarization layer and a second portion that covers the light emitting element, the second portion of the planarization layer, and a portion of the first insulation layer that is on the second portion of the planarization layer; and
a cathode electrode that is connected to the connection electrode and light emitting element, the cathode electrode over the first portion of the second insulation layer and the second portion of the second insulation layer.

24. The display apparatus of claim 23, wherein the second insulation layer comprises an organic insulating material having a plurality of particles.

25. The display apparatus of claim 23, wherein the cathode electrode is on an upper surface and an inclined surface of the first portion of the second insulation layer and is on an upper surface and an inclined surface of the second portion of the second insulation layer.

26. The display apparatus of claim 23, further comprising:
a contact wire on the second portion of the planarization layer, the contact wire supplying a voltage to the light emitting element;
wherein the first insulation layer partially covers the contact wire such that a portion of the contact wire that is not covered by the first insulation layer is in contact with the light emitting element.

27. The display apparatus of claim 26, wherein the contact wire extends from a signal line from the plurality of signal lines in a second direction that intersects the first direction.

28. The display apparatus of claim 26, wherein the connection electrode and the contact wire comprise a same material, and include a plurality of metal layers.
